(19) United States
(12) Patent Application Publication
(10) Pub. No.: US 2011/0147721 A1
(43) Pub. Date: Jun. 23, 2011

(54) POLARIZING FILM FOR DISPLAY DEVICE AND ORGANIC LIGHT EMITTING DIODE (OLED) DISPLAY DEVICE INCLUDING THE SAME

(75) Inventor: Byung-Uk HAN, Yongin-City (KR)

(73) Assignee: Samsung Mobile Display Co., Ltd, Yongin-City (KR)

(21) Appl. No.: 12/916,786

(22) Filed: Nov. 1, 2010

(30) Foreign Application Priority Data
Dec. 21, 2009 (KR) 10-2009-0128127

(51) Int. Cl. H01L 51/52; G02B 5/30

(52) U.S. Cl. 257/40; 257/E51.018

(57) ABSTRACT

A polarizing film includes an anti-glare layer that has a haze of 10 to 50%. An OLED display device includes a display panel including a device substrate on which one or more OLEDs are formed, and a polarizing film disposed at a viewing surface of the display panel. The polarizing film includes an anti-glare layer having a haze of 10 to 50%.

### CROSS-REFERENCE TO RELATED APPLICATION

This application claims the benefit of Korean Patent Application No. 10-2009-0128127, filed Dec. 21, 2009, in the Korean Intellectual Property Office, the disclosure of which is incorporated herein by reference.

### BACKGROUND

1. Field

An aspect of the described technology relates generally to a polarizing film for a display device and an organic light emitting diode (OLED) display device including the same, and a polarizing film for a display device and an OLED display device capable of removing a Newton's-ring phenomenon without deteriorating mechanical strength.

2. Description of the Related Art

Light weight and thinness of a flat panel display device enable the device to be used as a display device replacing a cathode-ray tube display device. Such a device may be a liquid crystal display device (LCD) or an organic light emitting diode (OLED) display device, for example. The OLED display device may be formed to be ultra thin, since it does not require a back light, and exhibits better brightness and viewing angle characteristics than an LCD.

In the OLED display device, an electron injected from a cathode and a hole injected from an anode recombine in an organic thin film layer to create an exciton. Light of a specific wavelength is generated by energy from the formed exciton. In order to facilitate the generation of light of a specific wavelength by the recombination of an electron and a hole, an anode from which a hole is injected may be formed of a material exhibiting a large work function, and a cathode from which an electron is injected may be formed of a metal material exhibiting a small work function.

In order to prevent a contrast ratio of an generated image from being degraded by a combination of reflected light incident onto the display device and light emitted from the display device, the flat panel display device may further include a polarizing film formed on a surface of the side of the display device from which the generated image is emitted and including a polarizing layer that deflects light to oscillate only in one direction.

In the OLED display device, a device substrate on which one or more OLEDs are formed may be coupled to an encapsulation substrate using a coupling member such as a sealant, so that the OLED display device can be sealed. However, a gap between the device substrate and the encapsulation substrate may cause optical interference of light emitted from the OLED, so that patterns in a concentric circle shape may appear on a surface of the encapsulation substrate to be reflected in an image generated by the device substrate. As a result, the contrast ratio and visibility of the image may be deteriorated and a Newton's ring (a type of interference pattern) may occur, causing distortion of the image.

In order to remove the Newton's ring, a cavity may be formed on the encapsulation substrate such that a gap between the encapsulation substrate and the device substrate maintains a predetermined distance. However, the mechanical strength of the encapsulation substrate may become degraded due to the presence of the cavity, resulting in damage such as cracking of the encapsulation substrate.

### SUMMARY

Aspects of the described technology provide a polarizing film for a display device, in which a Newton's ring phenomenon is removed using a polarizing film, so that a contrast ratio of an image and visibility may be prevented from being degraded without deteriorating the mechanical strength of an encapsulation substrate, and an organic light emitting diode (OLED) display device including the same.

According to an exemplary embodiment, a polarizing film for a display device includes an anti-glare layer that has a haze of 10 to 50%.

According to another exemplary embodiment, an OLED display device includes: a display panel including a device substrate on which one or more OLEDs are formed; and a polarizing film disposed at a viewing surface of the display panel. The polarizing film includes an anti-glare layer having a haze of 10 to 50%.

According to another exemplary embodiment, a display device includes a display device includes a display panel including a device substrate on which image generating elements are formed; an encapsulation substrate that faces the device substrate and that is coupled to the display panel by a coupling member that seals a space between the encapsulation substrate and the device substrate; and a polarizing film disposed at a surface of the encapsulation substrate opposite to a surface of the encapsulation substrate that faces the device substrate, wherein the polarizing film includes an anti-glare layer having a haze of 10 to 50%.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A is a cross-sectional view of an organic light emitting diode (OLED) display device according to an exemplary embodiment;

FIG. 1B is an enlarged cross-sectional view of part A of FIG. 1A;

FIG. 2 is a perspective view of a polarizing film of an OLED display device according to an exemplary embodiment;

FIG. 3A is a graph illustrating a ratio of recognizing the Newton's ring according to haze of the anti-glare layer;

FIG. 3B is a graph illustrating visibility of external light according to the haze of the anti-glare layer;

FIG. 3C is a graph illustrating a degree of transparency according to the haze of the anti-glare layer; and

FIGS. 4A through 6B are pictures of scattered particles according to examples of the invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

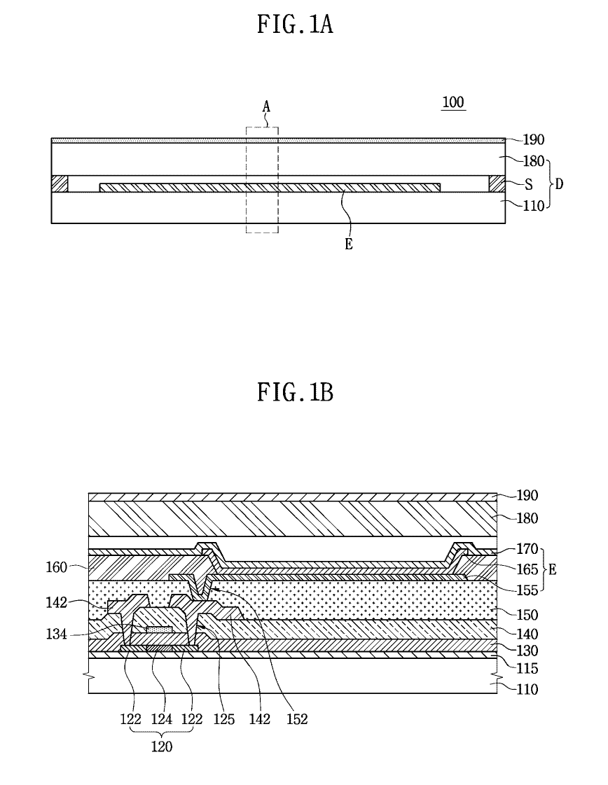

FIG. 1A is a schematic cross-sectional view of an organic light emitting diode (OLED) display device 100 according to an exemplary embodiment, and FIG. 1B is an enlarged cross-sectional view of part A of FIG. 1A. Referring to FIGS. 1A and 1B, the OLED display device 100 includes a device substrate 110, an encapsulation substrate 180, a display panel D and a polarizing filter 190. The device substrate 110 includes one or more OLEDs E. The encapsulation substrate 180 is disposed to face the device substrate 110. The display panel D includes a sealant coupling member that couples the device substrate 110 to the encapsulation substrate 180. The polarizing film 190 is disposed on the encapsulation substrate 180 of the display panel D.

The OLED E includes a lower electrode 155 that generates light of a predetermined color according to an external signal, an organic layer 165 including one or more emission layers (not separately shown) disposed on the lower electrode 155 and an upper electrode 170 disposed on the organic layer. As illustrated in FIG. 1B, in order to drive the OLED E, a thin film transistor is formed on the device substrate 110. The thin film transistor includes a semiconductor layer 120, a gate insulating layer 130, a gate electrode 134 and source/drain electrodes 142.

To fabricate the OLED display device 100 of FIG. 1B, a polysilicon layer (not shown) is formed on the device substrate 110 formed of glass, a synthetic resin or stainless steel. The polysilicon layer is etched to form the semiconductor layer 120.

The polysilicon layer may be formed by stacking an amorphous silicon layer on the device substrate 110, and crystallizing the amorphous silicon layer using a method selected from solid phase crystallization (SPC), rapid thermal annealing (RTA), metal induced crystallization (MIC), metal induced lateral crystallization (MILC), excimer laser annealing (ELA) crystallization, and sequential lateral solidification (SLS) crystallization.

In the OLED display device 100 according to the shown exemplary embodiment, in order to prevent diffusion of impurities on the device substrate 110 while the amorphous silicon layers are crystallized, a buffer layer 115 of SiNx, SiO₂ or a stacked layer thereof is formed on the device substrate 110, and crystallization of the amorphous silicon layer may be performed after the amorphous silicon layer is stacked on the buffer layer 115. However, the buffer layer 115 is not required in all aspects.

The gate insulating layer 130 is formed on the entire surface of the device substrate 110 including the semiconductor layer 120. After a first conductive material layer (not shown) is formed on the gate insulating layer 130, the first conductive material layer is etched, so that a gate electrode 134 is formed to correspond to a predetermined region of the semiconductor layer 120.

The first conductive material layer may be formed of a single layer of a material selected from the group consisting of tungsten (W), molybdenum (Mo), chromium (Cr), tungsten silicide (WSi₂), molybdenum silicide (MoSi₂), chromium silicide, aluminum (Al) and an alloy thereof or a multilayer in which an Al alloy is formed on a W, Cr or Mo alloy.

P- or N-type impurities are doped using the gate electrode 134 as a mask, so that source and drain regions 122 doped with impurities and a channel region 124 that is not doped with the impurities are formed in the semiconductor layer 120.

Here, the P-type impurities may be one selected from the group consisting of boron (B), Al, gallium (Ga) and indium (In), and the N-type impurities may be one selected from the group consisting of phosphorus (P), arsenic (As), antimony (Sb) and bismuth (Bi).

While it is described that the source and drain regions 122 of the semiconductor layer 120 are doped with impurities using the gate electrode 134 as a mask in the OLED display device 100 according to the exemplary embodiment, a photoresist layer (not shown) may be formed on the channel region 124 of the semiconductor layer 120 before forming the gate electrode 134, and an impurity doping process may be performed to form the source and drain regions 122 of the semiconductor layer 120.

An interlayer insulating layer 140 is formed on the device substrate 110 including the gate electrode 134, and the interlayer insulating layer 140 and the gate insulating layer 130 are etched to form a contact hole 125 exposing a part of the source and drain regions 122 of the semiconductor layer 120.

A second conductive material layer (not shown) is formed on the interlayer insulating layer 140, and then etched to form source and drain electrodes 142 connected to the source and drain regions 122 through the contact hole 125. Here, the second conductive material layer may be formed using an alloy such as molybdenum tungsten (MoW) and aluminum neodymium (Al-Nd).

A planarization layer 150 is formed on the source and drain electrodes 142, and then etched, so that a via hole 152 is formed exposing a part of one of the source and drain electrodes 142. The planarization layer 150 may be formed of a material selected from the group consisting of benzocyclobutene (BCB), polyimide (PI), polyamide (PA), an acrylic resin and a phenolic resin.

Also, while it is described that the planarization layer 150 is formed on the device substrate 110 including the source and drain electrodes 142 in the OLED display device according to one exemplary embodiment, instead of the planarization layer 150, a protection layer (not shown) of an inorganic insulating layer having a silicon oxide (SiO₂) layer, a silicon nitride (SiNx) layer or a stacked structure thereof may be formed on the device substrate 110 including the source and drain electrodes 142 in another embodiment. The planarization layer 150 may be formed on the protection layer (not shown).

A third conductive material layer (not shown) is formed on the planarization layer 150, and then etched, so that a lower electrode 155 connected to one of the source and drain electrodes 142 through the via hole 152 is formed. The third conductive material layer may be a transparent conductive layer such as ITO and IZO. A reflective layer (not shown) may be formed of a material selected from the group consisting of Al, an Al alloy, silver and a silver alloy, and a transparent conductive layer is formed on the reflective layer, so that the lower electrode 155 may have a double structure of the reflective layer and the transparent conductive layer.

A pixel defining layer 160 exposing a part of the lower electrode 155 is formed on the planarization layer 150. An organic layer 165 is disposed on the lower electrode 155 exposed by the pixel defining layer 160 and includes one or more emission layers (not separately shown). An upper electrode 170 is disposed on the organic layer 165, so that an OLED E is completed.

The pixel defining layer 160 may be formed of a material selected from the group consisting of polyimide, a benzocyclobutene series resin, a phenolic resin and acrylate.

It is to be understood that the structure of the OLEDs E of the OLED display device and the method of forming the OLED display device is not limited to what is described above and that other structures and methods may be used. It is also to be understood that the polarizing film described in more detail below may be used in other types of display devices besides OLED display devices.

Subsequently, a coupling member S is formed on the outside perimeter of the device substrate 110 on which the one or more OLEDs E are formed as a result of the above process. The device substrate 110 is coupled to an encapsulation substrate 180 disposed to face the device substrate 110 using the coupling member S, so that one or more OLEDs E formed on the device substrate 110 are sealed against air. Examples of material of the coupling member S include frit and/or a sealant.

Next, a polarizing film 190 is formed on the encapsulation substrate 180, so that the OLED display device 100 according to the exemplary embodiment is completed. While it is described that in the OLED display device 100 according to the exemplary embodiment, the device substrate 110 is coupled to the encapsulation substrate 180, and then the polarizing film 190 is formed on the encapsulation substrate 180, the device substrate 110 may be coupled to the encapsulation substrate 180 after the polarizing film 190 is formed on the encapsulation substrate 180.

Also, while it is described that the polarizing film 190 is formed on the encapsulation substrate 180 in the OLED display device 100 according to the exemplary embodiment, an OLED display device has a structure such that a predetermined image generated by the OLEDs E is directed in a direction of the device substrate 110, that is, when the OLED display device is a bottom emission type, the polarizing film 190 may be formed on the outside of the device substrate 110, that is, on the side of the device substrate 110 in which the OLEDs E are not formed.

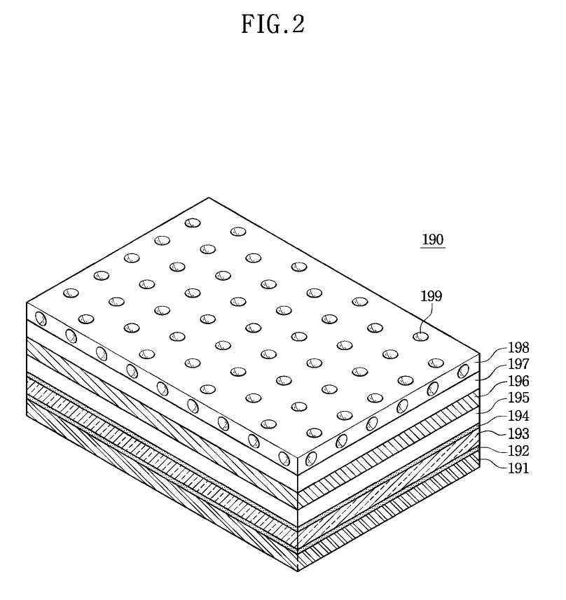

FIG. 2 is a perspective view of the polarizing film 190 of the OLED display device 100 according to an exemplary embodiment. Referring to FIG. 2, the polarizing film 190 includes a polarizing layer 196, an anti-glare layer 198, a first support layer 197 disposed between the polarizing layer 196 and the anti-glare layer 198, and a second support layer 195 disposed on an opposite side the polarizing layer 196 from where the first support layer 197 is disposed. The polarizing film 190 may further include a protection film (not shown) disposed on the outside of the anti-glare layer 198 in order to prevent a surface of the anti-glare layer 198 from being damaged.

The polarizing layer 196 may be an uniaxially elongated film formed by adsorbing a dichroic material such as iodine or a dichroic dye onto a hydrophilic polymer film such as a polyvinyl alcohol-based film, a partially formalized polyvinyl alcohol-based film, or an ethylene vinyl acetate copolymer-based partially saponified film. Alternatively, the hydrophilic polymer film may be a polyene-based alignment film such as a result of dehydration of polyvinyl alcohol or a result of dehydrochlorination of polyvinyl chloride, and taking into account process efficiency, a dichroic material such as iodine or a dichroic dye may be adsorbed to a hydrophilic polymer film such as polyvinyl alcohol (PVA) to be elongated and oriented.

While not required in all aspects, the shown first support layer 197 and the second support layer 195 may function to support the polarizing layer 196, and may be formed of a cellulose-based polymer such as tri acetate cellulose (TAC) taking into account polarizing characteristics and durability.

An adhesive may be used to strongly bond the first support layer 197 and the second support layer 195 to the polarizing layer 196. The adhesive may be an isocyanate-based adhesive, a PVA-based adhesive, a gelatin-based adhesive or a vinyl or latex-based adhesive.

While not required in all aspects, the shown polarizing film 190 further includes a release protection film 191 on the outside of the second support layer 195 to prevent pollution and damage caused by a moving or bonding process, and to be easily bonded to or separated from the device substrate 110 or the polarizing film 190.

The release protection film 191 may be formed of a material selected from the group consisting of a biaxially elongated and oriented polyolefin film, a polyester film, a thermoplastic norbornene-based resin film, a polycarbonate film, and a polybutyleneterephthalate film or a combination thereof, and may be formed of a material that is optically transparent, does not easily generate birefringence, and has high mechanical strength.

Further, while not required in all aspects, in order to improve a contrast ratio of a generated image, the shown polarizing film 190 includes a retardation film 193 between the second support layer 195 and the release protection film 191, and includes adhesion layers 192 and 194 between the retardation film 193 and the release protection film 191 and between the retardation film 193 and the second support layer 195 such that the retardation film 193 is strongly bonded to the retardation film 193 and the release protection film 191.

The adhesion layers 192 and 194 may be formed of a material including a polymer such as an acrylic polymer, a silicon-based polymer, polyester, polyurethane, polyamide, polyether, a fluorine-based polymer or a rubber-based polymer as a base polymer. For example, the adhesion layers 192 and 194 may be formed of an acrylic adhesive exhibiting excellent optical transparency, proper wettability, adhesive characteristics including cohesive and adhesive properties, and excellent weather resistance and thermal resistance.

The retardation film 193 changes a phase of incident light to prevent the incident light from being emitted to the outside by the changed phased when the incident light is reflected by the lower electrode 155 or the upper electrode 170 of the OLED display device E, so that a contrast ratio of the generated image can be enhanced.

The anti-glare layer 198 functions to cause internal scattering of the incident light. The anti-glare layer 198 may be condensed in a surface direction to form micro concavo-convex structures of gradual waviness in a serial manner on the condensed surface. Further, the anti-glare layer 198 may be formed of a resin including scattered particles 199 for scattering the incident light as shown.

Here, as illustrated in FIG. 2, the scattered particles 199 of the anti-glare layer 198 protrude outwardly from the anti-glare layer 198. However, it is understood that the scattered particles 199 may include scattered particles 199 inwardly inserted or embedded in the anti-glare layer 198. The scattered particles 199 create a haze caused by the scattered incident light. The particles 199 can be of the same or different materials as the anti-glare layer 198. While not limited thereto, the particles 199 range from about 1 μm to about 10 μm in diameter, and may comprise organic compounds that contain carbon.

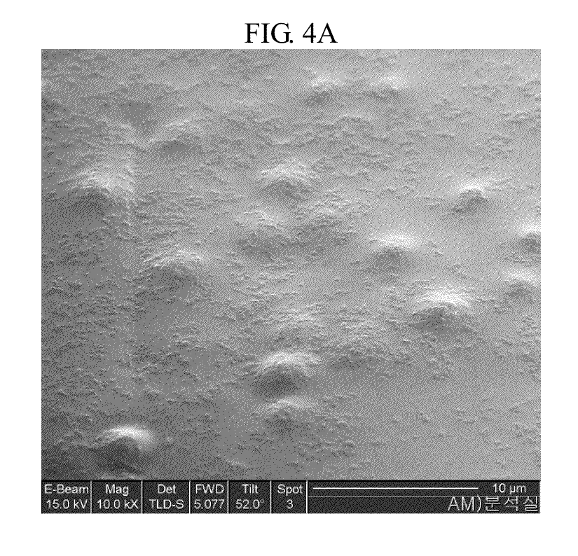

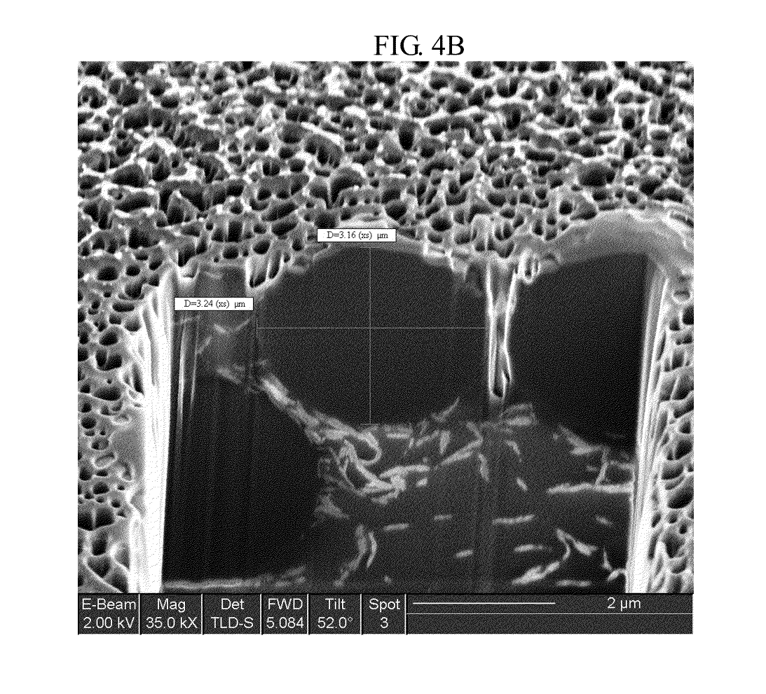

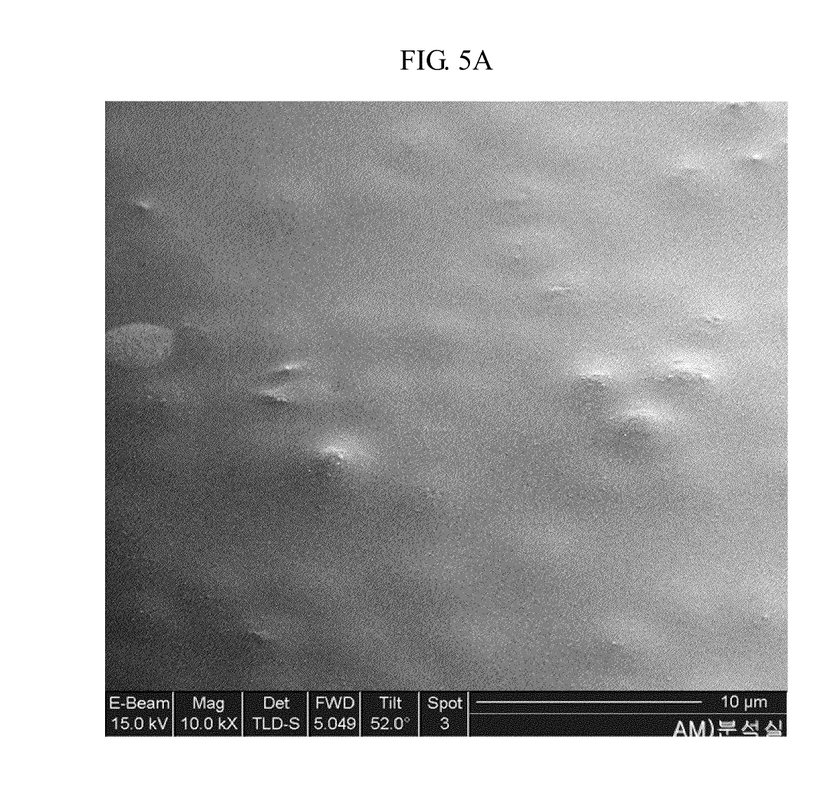

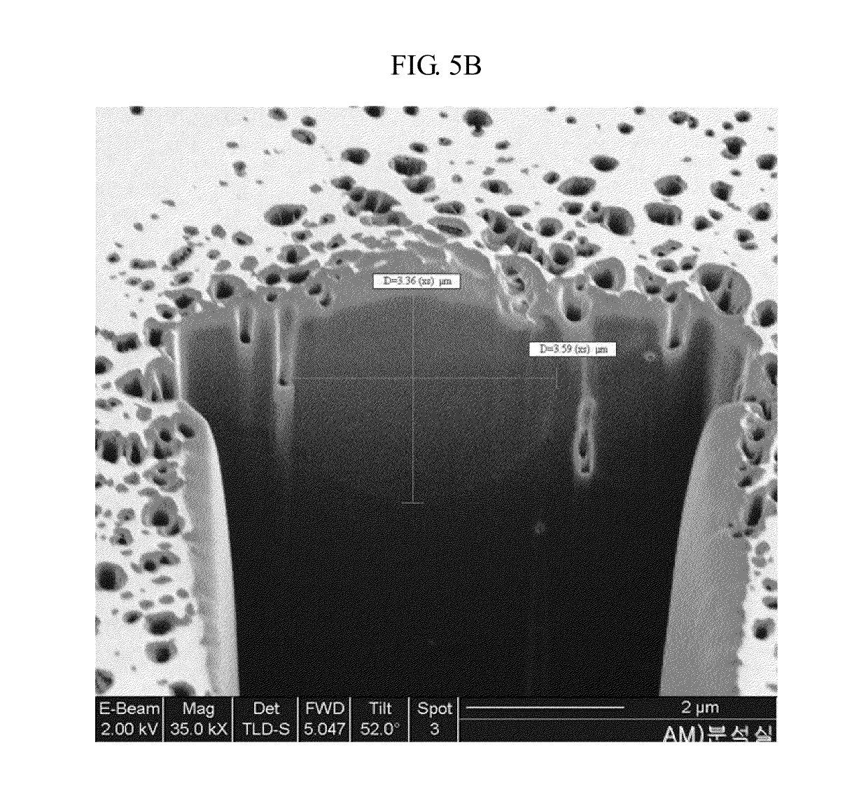

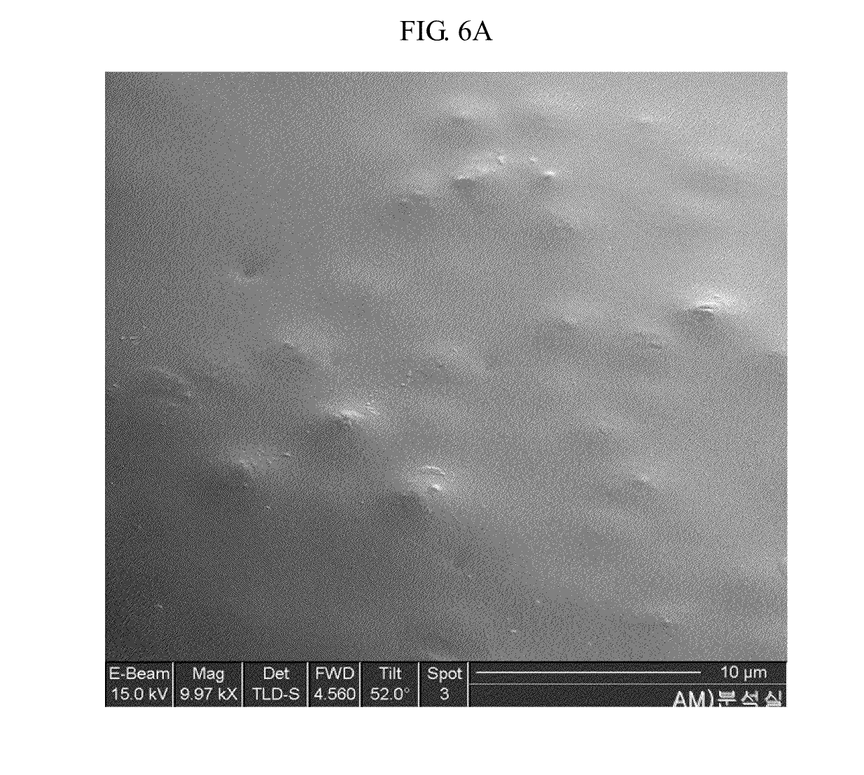

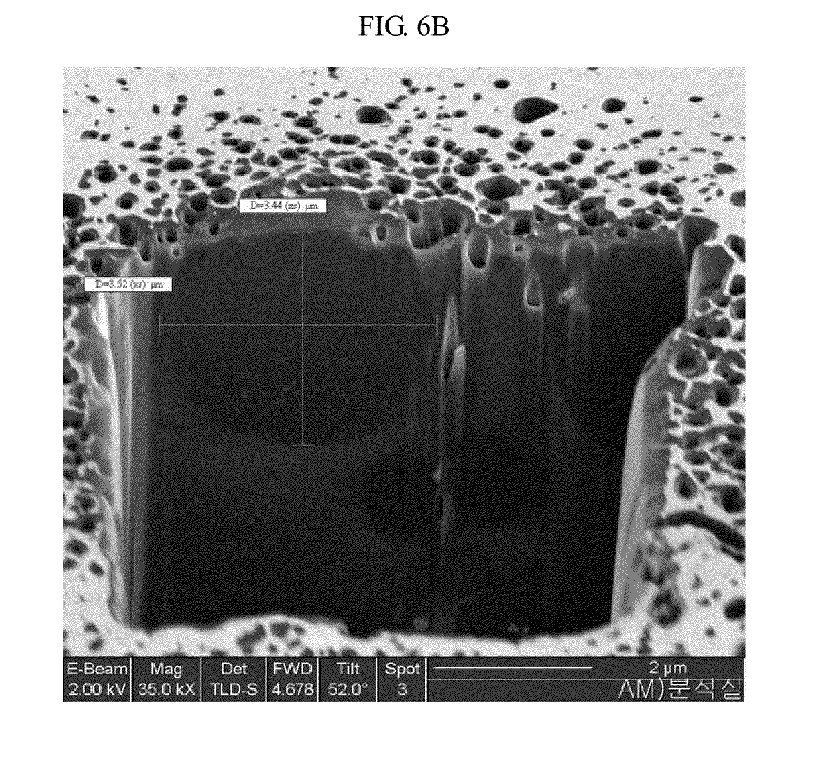

FIG. 4A to 6B show examples of an anti-glare layer condensed in a surface direction to form micro concavo-convex structures of gradual waviness in a serial manner on the condensed surface using the scattered particles. Specifically, FIG. 4A shows a 10,000 magnification of the anti-glare layer for a particle having a horizontal diameter of 3.2 μm, and a vertical diameter of 3.2 μm as shown in FIG. 4B, which is at 35,000 magnification. FIG. 5A shows a 10,000 magnification of the anti-glare layer for a particle having a horizontal diameter of 3.6 μm, and a vertical diameter of 3.4 μm as shown in FIG. 5B, which is at 35,000 magnification. FIG. 6A shows a 10,000 magnification of the anti-glare layer for a particle having a horizontal diameter of 3.5 μm, and a vertical diameter of 3.4 μm as shown in FIG. 6B, which is at 35,000 magnification.

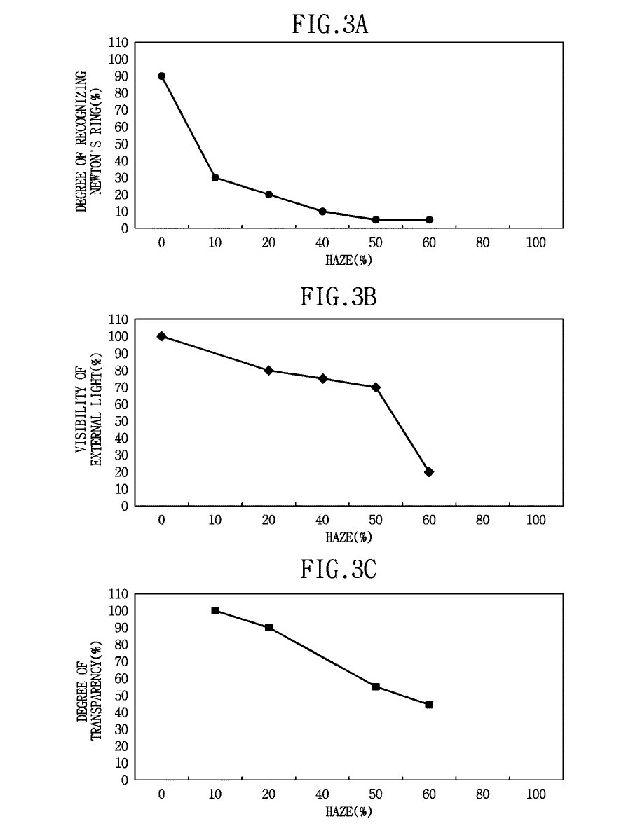

FIG. 3A is a graph illustrating a degree of recognizability of Newton's ring in an OLED display device including an anti-glare layer according to the haze of the anti-glare layer, FIG. 3B is a graph illustrating the visibility of external light according to the haze of the anti-glare layer, and FIG. 3C is a graph illustrating a degree of transparency according to the haze of the anti-glare layer.

Referring to FIG. 3A, it is observed that as the haze of the anti-glare layer 198 increases, a degree of recognizability of the Newton's ring decreases. In particular, a degree of recognizability of the Newton's ring is significantly lowered at a point where a haze of the anti-glare layer 198 is 10%. However, when a haze of the anti-glare layer 198 is equal to or higher than 50%, a degree of recognizing the Newton's ring is not considerably changed.

Referring to FIG. 3B, when a haze of the anti-glare layer 198 is equal to or lower than 50%, visibility of external light is only gradually lowered. However, when a haze of the anti-glare layer 198 exceeds 50%, visibility of external light is drastically lowered.

Referring to FIG. 3C, as the haze of the anti-glare layer 198 increases, a degree of transparency is gradually lowered.

Consequently, in the OLED display device according to an exemplary embodiment, a polarizing film disposed on a side of a display panel including a device substrate on which one or more OLEDs are formed and an encapsulation substrate coupled to the device substrate has a haze of 10 to 50%. Also, incident light is scattered by scattered particles included in an anti-glare layer to induce internal diffusion of external light, so that a degraded visibility of external light may be minimized and the Newton's ring may be removed.

Accordingly, a polarizing film disposed at a surface of a display panel of an OLED display device according to aspects of the present invention includes an anti-glare layer having a haze of 10 to 50% to induce internal scattering by the anti-glare layer, so that the visibility and contrast ratio of an generated image can be prevented from being degraded without weakening the mechanical strength of an encapsulation layer.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A polarizing film for a display device, the polarizing film comprising an anti-glare layer, wherein the anti-glare layer has a haze of 10 to 50%.

2. The polarizing film of claim 1, wherein the polarizing film further includes a polarizing layer, a first support layer disposed between the polarizing layer and the anti-glare layer, and a second support layer disposed on an opposite side of the polarizing layer such that the polarizing layer is between the first and second support layers.

3. The polarizing film of claim 2, further comprising a release protection layer disposed on an opposite side of the second support layer from the polarizing layer.

4. The polarizing film of claim 3, further comprising a retardation film disposed between the release protection layer and the second support layer.

5. The polarizing film of claim 4, further comprising a first adhesion layer disposed between the second support layer and the retardation film and a second adhesion layer disposed between the retardation film and the release protection layer.

6. The polarizing film of claim 5, wherein the first and second adhesion layers are formed of an acrylic polymer.

7. The polarizing film of claim 2, wherein the first support layer and the second support layer are formed of a cellulose-based polymer.

8. The polarizing film of claim 2, further comprising a protection film disposed on an opposite side of the anti-glare layer from the first support layer.

9. The polarizing film of claim 1, wherein the polarizing layer is formed of a hydrophilic polymer.

10. The polarizing film of claim 1, wherein the anti-glare film comprises a resin and scattered particles embedded in the resin.

11. The polarizing film of claim 1, wherein the anti-glare film comprises a resin and includes micro concavo-convex structures that form the haze.

12. An organic light emitting diode (OLED) display device, comprising:
a display panel including a device substrate on which one or more OLEDs are formed; and
a polarizing film disposed at a viewing surface of the display panel,
wherein the polarizing film includes an anti-glare layer having a haze of 10 to 50%.

13. The device of claim 12, wherein the display panel includes an encapsulation substrate disposed to face the device substrate, and a coupling member that couples the device substrate to the encapsulation substrate.

14. The device of claim 13, wherein the polarizing film is disposed on the encapsulation substrate.

15. The device of claim 12, wherein the polarizing film includes a polarizing layer, a first support layer disposed between the polarizing layer and the anti-glare layer, and a second support layer disposed on an opposite side of the polarizing layer such that the polarizing layer is between the first and second support layers.

16. The device of claim 15, wherein the polarizing film includes a release protection layer disposed on an opposite of the second support layer from the polarizing layer.

17. The device of claim 16, wherein the polarizing film includes a retardation film disposed between the release protection layer and the second support layer.

18. The device of claim 17, wherein the polarizing film includes an first adhesion layer disposed between the second support layer and the retardation film and a second adhesion layer disposed between the retardation film and the release protection layer.

19. The device of claim 18, wherein the first and second adhesion layers are formed of an acrylic polymer.

20. The device of claim 15, wherein the first support layer and the second support layer are formed of a cellulose-based polymer.

21. The device of claim 15, wherein the polarizing film includes a protection film disposed on an opposite side of the anti-glare layer from the first support layer.

22. The device of claim 15, wherein the polarizing layer is formed of a hydrophilic polymer.

23. The device of claim 12, wherein the anti-glare film comprises a resin and scattered particles embedded in the resin.
